(19) United States
(12) Patent Application Publication
(10) Pub. No.: US 2009/0309125 A1
(43) Pub. Date: Dec. 17, 2009

(54) GLASS FOR ENCAPSULATING OPTICAL ELEMENT AND LIGHT-EMITTING DEVICE ENCAPSULATED WITH GLASS

(75) Inventors: Syuji MATSUMOTO, Chiyoda-ku (JP); Nobuhiro Nakamura, Chiyoda-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: ASAHI GLASS COMPANY, LIMITED, Chiyoda-ku (JP)

(21) Appl. No.: 12/536,538

(22) Filed: Aug. 6, 2009

Related U.S. Application Data
(63) Continuation of application No. PCT/JP2008/051971, filed on Feb. 6, 2008.

(30) Foreign Application Priority Data
Feb. 7, 2007 (JP) 2007-028143

(51) Int. Cl. H01L 33/00; C03C 3/15; C03C 3/14

(52) U.S. Cl. 257/100; 501/50; 501/49

(57) ABSTRACT

A glass for encapsulating an optical element that can seal the optical element at a temperature in the vicinity of 500° C., and a glass-encapsulated light-emitting device encapsulated with the glass, are provided.

A glass for encapsulating an optical element, which is a glass consisting essentially of, in terms of mol % of oxide, from 35 to 55% of TeO₂, from 20 to 50% of B₂O₃, from 10 to 30% of ZnO, and from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the content of ZnO is at most 15%, the content of TeO₂ is at most 46%.

### TECHNICAL FIELD

The present invention relates to a glass, particularly, to a glass to be employed for encapsulating an optical element (light-emitting diode) and to a glass-encapsulated light-emitting device encapsulated with such a glass.

### BACKGROUND ART

Heretofore, as a material for encapsulating a light-emitting element, a resin such as an epoxy resin, a silicone or a fluororesin, is mainly employed. However, conventional light-emitting devices employing the above materials do not have sufficient light-emitting efficiency, and it has been difficult to employ such conventional light-emitting devices for common illumination or headlamps for automobiles. Under the circumstances, a glass has attracted attention as the material for encapsulating (Patent Document 1, Patent Document 2).

Patent Document 1: JP-A-7-330372

Patent Document 2: US2006/0231737A1

### DISCLOSURE OF THE INVENTION

### Problems to Be Solved by the Invention

However, the low-melting-point glass described in Patent Document 1, has a problem that since it contains fluorine (chemical symbol: F), the transparency of the glass is insufficient to be employed for common illumination or headlamps for automobiles. Further, there is also a problem that since fluorine is an expensive material, the price of a glass-encapsulated light-emitting device employing such a material becomes high.

Further, the glass described in Patent Document 2 has a problem that it has a glass-transition point (Tg) of at least 420° C. and it is not possible to seal a light-emitting element at a temperature of lower than 500° C.

### Means for Solving the Problems

The present invention provides the following.

(1) A glass for encapsulating an optical element, which is a glass consisting essentially of, in terms of mol % of oxide, from 35 to 55% of TeO₂, from 20 to 50% of B₂O₃, from 10 to 30% of ZnO, and from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the content of ZnO is at most 15%, the content of TeO₂ is at most 46%.

(2) The glass for encapsulating an optical element according to the above (1), wherein when the glass in an unsolidified molten state is cast into a carbon mold, the surface of the glass cast into the mold does not become opaque white.

(3) A glass for encapsulating an optical element, which is a glass consisting essentially of, in terms of mol % of oxide, from 35 to 55% of TeO₂, from 20 to 50% of B₂O₃, from 10 to 30% of ZnO, and from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the glass melted at 920° C. is cast into a carbon mold, the surface of the glass cast into the mold does not become opaque white.

(4) The glass for encapsulating an optical element according to any one of the above (1) to (3), which consists essentially of from 40 to 50% of TeO₂, from 25 to 45% of B₂O₃, from 15 to 27% of ZnO, and from 0.1 to 3% of Bi₂O₃, in terms of mol % of oxide.

(5) The glass for encapsulating an optical element according to any one of the above (1) to (4), which has an average linear coefficient of thermal expansion of from 70 to 120×10⁻⁷/° C. at a temperature of from 50 to 300° C., and a glass transition point of at most 420° C.

(6) The glass for encapsulating an optical element according to any one of the above (1) to (5), wherein when the content of ZnO is at most 15%, the content of TeO₂ is at most 46% in terms of mol % of oxide.

(7) The glass for encapsulating an optical element according to any one of the above (1) to (6), wherein in terms of mol % of oxide, the sum of 5 times the content of ZnO and 4 times the content of B₂O₃ is at least 200.

(8) The glass for encapsulating an optical element according to any one of the above (1) to (7), wherein the value of (B₂O₃+ZnO)/TeO₂ is at most 1.5.

(9) The glass for encapsulating an optical element according to any one of the above (1) to (8), wherein in terms of mol % of oxide, the sum of 5 times the content of ZnO and 4 times the content of B₂O₃ is at most 300.

(10) A glass-encapsulated light-emitting device comprising:
a glass,
an adhered member sealed in the glass; and
a substrate on which the adhered member is mounted;
wherein the glass is a glass consisting essentially of, in terms of mol % of oxide, from 35 to 55% of TeO₂, from 20 to 50% of B₂O₃, from 10 to 30% of ZnO, from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the content of ZnO is at most 15%, the content of TeO₂ is at most 46%.

### EFFECTS OF THE INVENTION

According to the present invention, it is possible to lower the glass-transition point without significantly increasing the average linear coefficient of thermal expansion, and to provide a glass for encapsulating an optical element capable of sealing the optical element at a temperature in the vicinity of 500° C., and a glass-encapsulated light-emitting device encapsulated with such a glass.

### BRIEF DESCRIPTION OF THE DRAWINGS

FIG. 1 is a cross-sectional view of a glass-encapsulated light-emitting device of the present invention.

### EXPLANATION OF SYMBOLS

100: Light-emitting element

110: Glass

120: Substrate

### BEST MODE FOR CARRYING OUT THE INVENTION

Embodiments of the present invention will be described in detail with reference to the attached drawing. In the drawing, corresponding portions are indicated by the corresponding symbols. The following embodiment is an example, and the present invention can be worked with various modifications within the scope not departing from the concept of the present invention.

First, the glass-encapsulated light-emitting device is described with reference to the drawing.

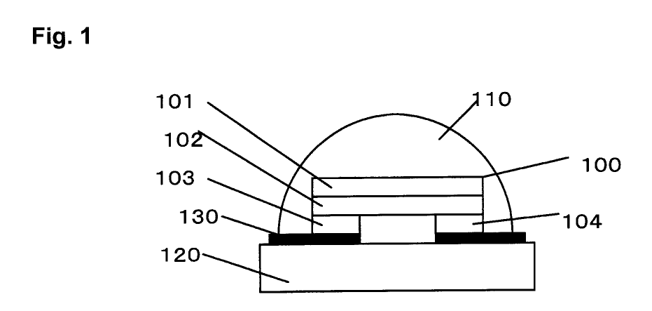

FIG. 1 is a cross-sectional view of a glass-encapsulated light-emitting device of the present invention. The glass-encapsulated light-emitting device of the present invention has a light-emitting element (such as a light-emitting diode) 100 being an adhered member, a glass 110 being a encapsulating material for encapsulating the light-emitting element 100, and a substrate 120 on which the light-emitting element 100 is mounted and on which a wiring 130 is formed.

The light-emitting element 100 has a substratum 101, an LED 102, a positive electrode 103 and a negative electrode 104. The LED 102 is an LED emitting UV rays or blue light within a wavelength range of from 360 to 480 nm, which is an LED (InGaN type LED) having a quantum well structure using InGaN formed by adding In to GaN as a light-emitting layer. The average linear coefficient of thermal expansion (a) of the substratum 101 is from 70×10⁻⁷ to 90×10⁻⁷/° C. Usually, a sapphire substrate having an average linear coefficient of thermal expansion (a) of about 80×10⁻⁷/° C. is employed as the substratum 101.

Next, the glass for encapsulating an optical element of the present invention will be described.

The glass-transition point (Tg) of the glass for encapsulating an optical element of the present invention is preferably at most 420° C., more preferably at most 410° C. Further, the glass-transition point (Tg) is preferably at least 360° C.

The average linear coefficient of thermal expansion (a) of the glass for encapsulating an optical element of the present invention at a temperature of from 50 to 300° C. is preferably at most 120×10⁻⁷/° C., more preferably at most 116×10⁻⁷/° C., particularly preferably at most 115×10⁻⁷/° C. Here, the average linear coefficient of thermal expansion (a) is preferably at least 70×10⁻⁷/° C. If it is less than 70×10⁻⁷/° C., the glass transition point becomes high. It is more preferably at least 75×10⁻⁷/° C.

The glass for encapsulating an optical element of the present invention preferably has an average linear coefficient of thermal expansion of from 70 to 120×10⁻⁷/° C. at a temperature of from 50 to 300° C., and a glass transition point of at most 420° C.

Now, the composition of the glass for encapsulating an optical element of the present invention will be described, wherein mol % is abbreviated to %.

TeO₂ is a network former of the glass, and thus, it is essential. If the content is less than 35%, the refractive index becomes small or the glass transition point becomes high. The content is preferably at least 40%, particularly preferably at least 43%. If the content exceeds 55%, the average linear coefficient of thermal expansion becomes large. The content is preferably at most 50%, particularly preferably at most 48%.

B₂O₃ is a component for forming the bone structure of the glass, and thus, it is essential. If the content is less than 20%, devitrification tends to occur. Or the glass is not formed. The content is preferably at least 25%, particularly preferably at least 27%. If the content exceeds 50%, the refractive index become small, or the chemical durability such as water resistance decreases. The content is preferably at most 45%, particularly preferably at most 40%.

ZnO is a component for stabilizing the glass, and thus, it is essential. When the content is less than 10%, the glass becomes unstable, and devitrification tends to occur. The content is preferably at least 15%, particularly preferably at least 18%. If the content exceeds 30%, it may be necessary to melt the glass at a temperature higher than 980° C. The content is preferably at most 27%, particularly preferably at most 25%.

Here, the value of (B₂O₃+ZnO)/TeO₂ is at least 0.9. If it is less than 0.9, the glass transition point becomes at least 420° C., and it may not be possible to seal the light-emitting element at a temperature in the vicinity of 500° C. If the value exceeds 1.5, the glass transition point becomes high or the chemical durability such as water resistance decreases. The value is preferably at most 1.4. Further, the value of (5×ZnO+4×B₂O₃) is preferably at least 200. If the value is less than 200, the glass transition point becomes at least 420° C., and it may not be possible to seal the light-emitting element at a temperature in the vicinity of 500° C. If the value exceeds 300, the glass transition point becomes high or the chemical durability such as the water resistance decreases. The value is preferably at most 250. Further, when ZnO is less than 16%, TeO₂ is preferably less than 47%. If TeO₂ is at least 47%, devitrification tends to occur. When the content of ZnO is at most 15%, the content of TeO₂ is preferably at most 46%.

Y₂O₃ is not essential, but it may be contained in an amount of at most 5% in order to suppress devitrification. If the content exceeds 5%, the glass transition point becomes high or the refractive index becomes low. The content is preferably at most 3%, particularly preferably at most 2%. When Y₂O₃ is contained, the content is preferably at least 0.1%, particularly preferably at least 0.2%.

La₂O₃ is not essential, but it may be contained in an amount of at most 5% in order to suppress devitrification. If the content exceeds 5%, the glass transition point becomes high or the refractive index becomes low. The content is preferably at most 3%, particularly preferably at most 2%. When La₂O₃ is contained, the content is preferably at least 0.1%, particularly preferably at least 0.2%.

Gd₂O₃ is not essential, but it may be contained in an amount of at most 5% in order to suppress devitrification. If the content exceeds 5%, the glass transition point becomes high. The content is preferably at most 3%, particularly preferably at most 2%. When Gd₂O₃ is contained, the content is preferably at least 0.1%, particularly preferably at least 0.2%.

Bi₂O₃ is not essential, but it may be contained in an amount of at most 5% in order to suppress devitrification. If the content exceeds 5%, the internal transmittance becomes low. The content is preferably at most 3%, particularly preferably at most 2%. When Bi₂O₃ is contained, the content is preferably at least 0.1%, particularly preferably at least 0.2%.

One type or a combination of at least two types selected from the group consisting of Y₂O₃, La₂O₃, Gd₂O₃ and Bi₂O₃, are components for suppressing devitrification, and are essential. Here, the content of said one type of these components or said combination of at least two types thereof is at least 0.1%. The content is particularly preferably at least 1%. Further, if the content exceeds 5%, the glass transition point becomes high. It is preferably at most 3%.

The glass for encapsulating an optical element of the present invention preferably consists essentially of from 40 to 50% of TeO₂, from 25 to 45% of B₂O₃, from 15 to 27% of ZnO and from 0.1 to 3% of Bi₂O₃, in terms of mol % of oxide wherein the value of (B₂O₃+ZnO)/TeO₂ is at least 0.9 and the glass preferably contains substantially no fluorine.

In the glass for encapsulating an optical element of the present invention, the phrase “contains substantially no fluorine” means that fluorine is not positively contained and that the content is less than 0.1% in terms of mol % of oxide.

The glass for encapsulating an optical element of the present invention consists essentially of the above components, but other components such as BaO, WO₃, GeO₂, TiO₂, Ga₂O₃ or Ta₂O₅ may be contained within a scope not impairing the effect of the present invention. Here, the glass of the present invention preferably contains substantially no PbO. Here, the glass of the present invention is preferably producible by melting a raw material at a temperature of at most 980° C. Otherwise, it becomes difficult to melt the glass by using a crucible made of gold (melting point: 1,063° C.), it becomes necessary to melt the glass by using a crucible made of platinum or a platinum alloy, and as a result, platinum may be melt into the glass to decrease the transmittance.

The substrate 120 is, for example, a rectangular alumina substrate having a purity of from 98.0 to 99.5% and having a thickness of from 0.5 to 1.2 mm. It is preferably a square alumina substrate having a purity of from 99.0% to 99.5% and a thickness of from 0.7 to 1.0 mm. Here, the wiring 130 formed on a surface of the substrate 120 is gold wiring produced by gold pasting.

### EXAMPLES

In the following, the present invention will be specifically described with reference to Examples and Comparative Examples, but it is a matter of course that the present invention is not construed as limited to these Examples.

With respect to each of Examples 1 and 18, raw materials were blended so as to have the composition shown in the Table in mol % to prepare 500 g of a blended raw material. Next, the blended raw material was put in a crucible made of gold having a capacity of 300 cc, and was melted at 920° C. for 2 hours. At this time, the raw material was stirred by a stirrer made of gold for 1 hour to homogenize the molten glass. The homogenized molten glass was cast into a carbon mold to be molded into a plate shape. This plate-shaped glass was immediately put into another electric furnace of 410° C., the temperature was maintained for 1 hour, and the glass was gradually cooled to room temperature in 12 hours.

With respect to each of Examples 2 to 17 and Examples 19 to 21, raw materials were blended to have the composition shown in the Table in mol %, to prepare 100 g of a blended raw material. Next, the blended raw material was put in a crucible made of gold having a capacity of 100 cc and was melted at 920° C. for 1 hour. At this time, the entire crucible was swung a few times to stirrer and homogenize the molten glass. The homogenized molten glass was cast into a carbon mold to be molded into a plate shape. This plate-shaped glass was immediately put into another electric furnace of 410° C., the temperature was maintained for 1 hour, and the glass was gradually cooled to a room temperature for 12 hours.

Here, Examples 1 to 17 are Examples of the present invention, and Examples 18 to 21 are Comparative Examples.

With respect to each glass obtained, the glass transition point Tg (unit: ° C.), the yield point At (unit: ° C.), the average linear coefficient of thermal expansion α (unit: 10⁻⁷/° C.), the refractive index n_{d} and the dispersion υ_{d} were measured by the following measurement methods.

Tg: 150 mg of the sample in a powder form was put in a platinum pan, and Tg was measured by using a thermal analyzer TG/DTA6300 (model name) manufactured by SII Inc.

At: With respect to a sample cut into a cylindrical shape having a diameter of 5 mm and a length of 20 mm, At was measured under the temperature-rising speed of 5° C./min by using a thermomechanical analyzer DILATOMETER5000 (model name) manufactured by MAC Science Co., Ltd.

α: With respect to a sample cut into a cylindrical shape having a diameter of 5 mm and a length of 20 mm, the linear coefficient of thermal expansion was measured under a temperature-rising speed of 5° C./min by using the above thermomechanical analyzer. Expansion coefficients within a range of from 50 to 300° C. were measured at intervals of 25° C., and the average was designated as α.

Presence or absence of devitrification: When the molten glass is cast into the carbon mold, devitrification may occur in a few minutes before the glass is solidified. A sample whose surface became partially opaque white is designated as Δ. Here, the “opaque white” means a case where a opaque white is clearly visually observable on a surface of molten glass within three minutes after the molten glass is cast into the carbon mold. Here, when the opaque white is notable, typically, an opaque portion having a size of at least 10 mm in diameter is formed.

Refractive index n_{d}: The glass was cut into a plate shape of 20 mm square and 5 mm thick, its two continuing surfaces were subjected to optical polishing, and the refractive index was measured by using a precision spectrometer KPR-1 (model name) manufactured by Kalnew Kogaku.

Dispersion υ_{d}: At the same time as the above, υ_{d} was measured by using the precision spectrometer KPR-1 (model name) manufactured by Kalnew Kogaku.

Tables 1 and 2 show the results.

TABLE 1

| | Ex. 1 | Ex. 2 | Ex. 3 | Ex. 4 | Ex. 5 | Ex. 6 | Ex. 7 | Ex. 8 | Ex. 9 | Ex. 10 |
|---|---|---|---|---|---|---|---|---|---|---|
| TeO₂ | 47 | 50 | 50 | 50 | 47 | 47 | 45 | 45 | 45 | 45 |
| B₂O₃ | 28 | 24 | 29 | 31 | 32 | 34 | 29 | 34 | 36 | 39 |
| ZnO | 24 | 25 | 20 | 18 | 20 | 18 | 25 | 20 | 18 | 15 |
| (B₂O₃ + ZnO)/TeO₂ | 1.11 | 0.98 | 0.98 | 0.98 | 1.11 | 1.11 | 1.20 | 1.20 | 1.20 | 1.20 |
| 5 × ZnO + 4 × B₂O₃ | 232 | 221 | 216 | 214 | 228 | 226 | 241 | 236 | 234 | 231 |
| WO₃ | | | | | | | | | | |
| BaO | | | | | | | | | | |
| GeO₂ | | | | | | | | | | |
| TiO₂ | | | | | | | | | | |
| Ga₂O₃ | | | | | | | | | | |
| Y₂O₃ | | | | | | | | | | |
| La₂O₃ | | | | | | | | | | |
| Gd₂O₃ | | | | | | | | | | |
| Bi₂O₃ | 1 | 1 | 1 | 1 | 1 | 1 | 1 | 1 | 1 | 1 |
| Ta₂O₅ | | | | | | | | | | |
| Tg (° C.) | 390 | 385.5 | 386.5 | 384 | 391 | 388 | 397.5 | 394 | 390 | 381 |
| At (° C.) | 430 | 414 | 418 | 413 | 423 | 419 | 431 | 428 | 423 | 413 |
| α (×10⁻⁷/° C.) | 105 | 117 | 115 | 114 | 112 | 113 | 111 | 111 | 112 | 112 |
| n_{d} | 1.879 | | | | | | | | | |
| ν_{d} | 26 | | | | | | | | | |
| Devitrification | | | | | | | | | | |

TABLE 2

| | Ex. 11 | Ex. 12 | Ex. 13 | Ex. 14 | Ex. 15 | Ex. 16 | Ex. 17 | Ex. 18 | Ex. 19 | Ex. 20 | Ex. 21 |
|---|---|---|---|---|---|---|---|---|---|---|---|
| TeO₂ | 45 | 45 | 45 | 45 | 43 | 46 | 46 | 45 | 47 | 45 | 50 |
| B₂O₃ | 34 | 34 | 32 | 30 | 34 | 33 | 34 | 18 | 37 | 35 | 29 |
| ZnO | 20 | 18 | 20 | 20 | 20 | 19 | 19 | 15 | 15 | 20 | 21 |
| (B₂O₃ + ZnO)/TeO₂ | 1.20 | 1.16 | 1.16 | 1.11 | 1.26 | 1.13 | 1.15 | 0.73 | 1.11 | 1.22 | 1.00 |
| 5 × ZnO + 4 × B₂O₃ | 236 | 226 | 228 | 220 | 236 | 227 | 231 | 147 | 223 | 240 | 221 |
| WO₃ | | | | | 2 | | | | | | |
| BaO | | 2 | | | | | | | | | |
| GeO₂ | | | | | | | | 5 | | | |
| TiO₂ | | | | | | | | 1 | | | |
| Ga₂O₃ | | | | | | | | 6 | | | |
| Y₂O₃ | 0.5 | 0.5 | 0.5 | 0.5 | 0.5 | 0.5 | 0.3 | 0.5 | | | |
| La₂O₃ | 0.5 | 0.5 | 0.5 | 0.5 | 0.5 | 0.5 | 0.2 | 0.5 | | | |
| Gd₂O₃ | | | | | | | | 3 | | | |
| Bi₂O₃ | | | 2 | 4 | | 1 | 0.5 | 3 | 1 | | |
| Ta₂O₅ | | | | | | | | 3 | | | |
| Tg (° C.) | 399 | 400 | 405 | 403 | 401 | 408 | 404 | 450 | 381 | 390 | 380 |
| At (° C.) | 433 | 435 | 440 | 440 | 437 | 442 | 436 | 490 | 413 | 425 | 413 |
| α (×10⁻⁷/° C.) | 103 | 105 | 101 | 102 | 105 | 103 | 103 | 86 | 117 | 105 | 114 |
| n_{d} | | | | | | | | 1.940 | | | |
| ν_{d} | | | | | | | | 24.8 | | | |
| Devitrification | | | | | | | | | Δ | Δ | Δ |

### Example 1

A glass of Example 1 was cut into a glass plate having a thickness of 1.5 mm and a size of 3 mm×3 mm, and its both surfaces were subjected to mirror polishing.

Meanwhile, an alumina substrate (thickness: 1 mm; size: 14 mm×14 mm) on which a gold wiring pattern is formed, and an LED (product name: E1C60-0B011-03) manufactured by Toyoda Gosei Co., Ltd. on which connecting bumps were formed, were prepared, and this LED was flip-chip mounted on the alumina substrate. Further, in order to inhibit generation of bubbles on an interface with a glass substrate, the alumina substrate on which the LED was mounted was put in an electric furnace (IR heating apparatus), and was subjected to a heating treatment of 620° C. The temperature-raising speed was set to 300° C./min, the time duration at 620° C. was set to 2 minutes, and the temperature-falling speed was set to be 300° C./min. Here, the bubbles on the interface between the glass and the substrate are generated by a reaction of the glass with organic contaminants adhered to a surface of the substrate when the glass is softened. Then, the bubbles generated refract light emitted from the light-emitting element, which may decrease the brightness of the light-emitting element or change the emission distribution of the light-emitting device. For this reason, before encapsulating the LED with the glass, the substrate on which the LED is mounted is heated so as to reduce the amount of organic contaminants adhered to the substrate surface to inhibit generation of the bubbles. According to several experiments, the heating temperature is preferably around 600° C. Further, the heating time is preferably around 2 minutes considering the influence of heat on the LED.

On the LED that had been flip-chip mounted, a glass plate in which a phosphor was dispersed was placed, and they were put in an electric furnace and heated to 500° C. at a temperature-rising speed of 25° C./min, the temperature was maintained for 5 minutes to soften and flow the glass to encapsulate the LED. Thereafter, cooling was conducted at a speed of 25° C./min.

The glass encapsulating the LED was visually observed, but no bubble was recognized in the vicinity of the surface.

DC voltage was applied to the glass-encapsulated LED element thus obtained, and as a result, emission of blue light was observed.

The light-emission starting voltage was 2.4 V, and it was the same as that in a case of bear chip. This indicates that the light-emitting layer of the LED element was not damaged.

### Example 2

The plate-shaped glass of Example 1 was cut into blocks having a size of from 8 to 25 mm. A few pieces of these blocks were pulverized into a glass powder by using an alumina mortar. Although the maximum particle size of the glass powder was not measured, but from the result of visual observation, it is assumed to be at most 50 μm.

37.5 g of the glass powder and 5 g of an yellow phosphor P46-Y3 (cerium-added YAG powder) manufactured by Kasei Optonix, Ltd. were mixed to prepare a mixed powder.

42.5 g of this mixed powder and 5 pieces of the blocks (total mass=62.5 g) were put in a gold crucible having a capacity of 100 cc, and the crucible was left in an electric furnace of 650° C. for 5 minutes to remelt the glass and disperse the phosphor in the molten glass at the same time.

The crucible was taken out after a lapse of 5 minutes, and the molten glass in which the phosphor was dispersed was cast into a carbon mold to form it into a plate shape having a thickness of about 7 mm. This plate-shaped glass was immediately put into another electric furnace of 410° C., and the temperature was maintained for 1 hour, and thereafter, it was cooled to room temperature in 12 hours.

The LED element was encapsulated in the same manner as Example 1, and DC voltage was applied, and as a result, emission of white light was confirmed.

### INDUSTRIAL APPLICABILITY

The glass for encapsulating an optical element of the present invention, is usable for sealing an LED element to be employed for common illumination or headlamps for automobiles.

The entire disclosure of Japanese Patent Application No. 2007-028143 filed on Feb. 7, 2007 including specification, claims, drawings and summary is incorporated herein by reference in its entirety.

What is claimed is:

1. A glass for encapsulating an optical element, which is a glass consisting essentially of, in terms of mol % of oxide, from 35 to 55% of TeO₂, from 20 to 50% of B₂O₃, from 10 to 30% of ZnO, and from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the content of ZnO is at most 15%, the content of TeO₂ is at most 46%.

2. The glass for encapsulating an optical element according to claim 1, wherein when the glass in an unsolidified molten state is cast into a carbon mold, the surface of the glass cast into the mold does not become opaque white.

3. A glass for encapsulating an optical element, which is a glass consisting essentially of, in terms of mol % of oxide, from 35 to 55% of TeO₂, from 20 to 50% of B₂O₃, from 10 to 30% of ZnO, and from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the glass melted at 920° C. is cast into a carbon mold, the surface of the glass cast into the mold does not become opaque white.

4. The glass for encapsulating an optical element according to claim 1, which consists essentially of from 40 to 50% of TeO₂, from 25 to 45% of B₂O₃, from 15 to 27% of ZnO, and from 0.1 to 3% of Bi₂O₃ in terms of mol % of oxide.

5. The glass for encapsulating an optical element according to claim 3, which consists essentially of from 40 to 50% of TeO₂, from 25 to 45% of B₂O₃, from 15 to 27% of ZnO, and from 0.1 to 3% of Bi₂O₃ in terms of mol % of oxide.

6. The glass for encapsulating an optical element according to claim 1, which has an average linear coefficient of thermal expansion of from 70 to 120×10⁻⁷/° C. at a temperature of from 50 to 300° C., and a glass transition point of at most 420° C.

7. The glass for encapsulating an optical element according to claim 3, which has an average linear coefficient of thermal expansion of from 70 to 120×10⁻⁷/° C. at a temperature of from 50 to 300° C., and a glass transition point of at most 420° C.

8. The glass for encapsulating an optical element according to claim 3, wherein when the content of ZnO is at most 15%, the content of TeO₂ is at most 46% in terms of mol % of oxide.

9. The glass for encapsulating an optical element according to claim 1, wherein in terms of mol % of oxide, the sum of 5 times the content of ZnO and 4 times the content of B₂O₃ is at least 200.

10. The glass for encapsulating an optical element according to claim 3, wherein in terms of mol % of oxide, the sum of 5 times the content of ZnO and 4 times the content of B₂O₃ is at least 200.

11. The glass for encapsulating an optical element according to claim 1, wherein the value of (B₂O₃+ZnO)/TeO₂ is at most 1.5.

12. The glass for encapsulating an optical element according to claim 3, wherein the value of (B₂O₃+ZnO)/TeO₂ is at most 1.5.

13. The glass for encapsulating an optical element according to claim 1, wherein in terms of mol % of oxide, the sum of 5 times the content of ZnO and 4 times the content of B₂O₃ is at most 300.

14. The glass for encapsulating an optical element according to claim 3, wherein in terms of mol % of oxide, the sum of 5 times the content of ZnO and 4 times the content of B₂O₃ is at most 300.

15. A glass-encapsulated light-emitting device comprising:
a glass,
an adhered member sealed in the glass; and
a substrate on which the adhered member is mounted;
wherein the glass is a glass consisting essentially of, in terms of mol % of oxide, from 35 to 55% of TeO₂, from 20 to 50% of B₂O₃, from 10 to 30% of ZnO, from 0.1 to 5% of one type or a combination of at least two types selected from the group consisting of Y₂O₃, La₂O₃, Gd₂O₃ and Bi₂O₃, wherein the value of (B₂O₃+ZnO)/TeO₂ is at least 0.9, the glass contains substantially no fluorine, and when the content of ZnO is at most 15%, the content of TeO₂ is at most 46%.
